(19) United States
(12) Patent Application Publication
(10) Pub. No.: US 2012/0320301 A1
(43) Pub. Date: Dec. 20, 2012

(54) INTEGRATED CIRCUIT CHIP ON FILM AND LIQUID CRYSTAL DISPLAY INCLUDING THE SAME

(76) Inventors: Ok-Kwon SHIN, Asan-si (KR); Jong Min LEE, Suwon-si (KR); Sun Kyu SON, Suwon-si (KR); Young-Il BAN, Hwaseong-si (KR)

(21) Appl. No.: 13/279,824

(22) Filed: Oct. 24, 2011

(30) Foreign Application Priority Data
Jun. 17, 2011 (KR) 10-2011-0059202

(51) Int. Cl. G02F 1/136; H03K 3/00

(52) U.S. Cl. 349/50; 327/108

(57) ABSTRACT

Provided is a liquid crystal display including: a liquid crystal panel, a plurality of display signal lines disposed in the liquid crystal panel, a plurality of diodes including a first diode and a second diode. The first diode is connected to each of the display signal lines in a reverse direction and the second diode is connected to each of the display signal lines in a forward direction. The liquid crystal display further includes a plurality of first dummy pads and a plurality of second dummy pads disposed on IC chips which are mounted on a film which is connected to the display panel. A first dummy voltage line is connected to the first dummy pads, a second dummy voltage line is connected to the second dummy pads, and the first dummy pads and the second dummy pads are each adapted to receive a driving voltage.

### CROSS-REFERENCE TO RELATED APPLICATION

This application claims priority to of Korean Patent Application No. 10-2011-0059202 filed on Jun. 17, 2011, the disclosure of which is hereby incorporated by reference herein in its entirety.

### BACKGROUND OF THE INVENTION

(a) Technical Field

The present disclosure relates to an integrated circuit chip on a film and a liquid crystal display including the same.

(b) Description of the Related Art

A liquid crystal display, which is one of the more common types of flat panel displays currently in use, includes two sheets of substrates with electrodes and a liquid crystal layer interposed therebetween. The liquid crystal display applies voltage to the electrodes and rearranges liquid crystal molecules of the liquid crystal layer, thereby controlling an amount of transmitted light.

The liquid crystal display includes a liquid crystal panel displaying images and a driving circuit supplying an image signal to the liquid crystal panel.

Static electricity may be accumulated to the panel during the manufacturing process and transportation of the liquid crystal panel and in the driving of the liquid crystal display. For example, the static electricity may be input to the driving circuit through a display signal line of the liquid crystal display, such that a defect in the liquid crystal display occurs.

### SUMMARY OF THE INVENTION

The present invention has been made in an effort to provide a liquid crystal display which may prevent static electricity from occurring in driving of the liquid crystal display.

An exemplary embodiment of the present invention provides a liquid crystal display including: a liquid crystal panel s, a plurality of display signal lines disposed in the liquid crystal panel, a plurality of diodes including a first diode and a second diode. The first diode is connected to each of the display signal lines in a reverse direction and the second is connected to each of the display signal lines in a forward direction. The liquid crystal display further includes a first dummy voltage line connected to the first diode connected to the display signal lines in the reverse direction, a second dummy voltage line connected to the second diode connected to the display signal lined in the forward direction, a plurality of film connected to the liquid crystal panel. An integrated circuit (IC) chip supplying driving signals to the liquid crystal panel is mounted on the chip. The liquid crystal display further includes a plurality of first dummy pads and a plurality of second dummy pads disposed on the IC chips on the film, in which the first dummy voltage line is connected to the first dummy pads, the second dummy voltage line is connected to the second dummy pads, and the first dummy pads and the second dummy pads are each adapted to receive a driving voltage.

The liquid crystal display further may include a driving voltage supply unit adapted to supply a first driving voltage to the first dummy pads.

The liquid crystal display further may include a driving voltage supply unit adapted to supply a second driving voltage to the second dummy pads.

The first dummy pads may be connected to each end of the first dummy voltage line.

The second dummy pads may be connected to each end of the second dummy voltage line.

The driving voltage supply unit may be a printed circuit board (PCB).

The first diode and the second diode may be connected to each other in series.

The first diode and the second diode may be disposed between an adjacent pair of the display signal lines.

The liquid crystal display further may include a plurality of driving signal lines disposed on the film, and the driving signal lines may be connected to the IC chip and to the display signal lines.

A portion of the first dummy voltage lines may be disposed on the liquid crystal panel and a remaining portion of the first dummy voltage lines may be disposed on the film.

A portion of the second dummy voltage lines may be disposed on the liquid crystal panel and a remaining portion of the second dummy voltage lines may be disposed on the film.

In accordance with an exemplary embodiment of the present invention, a film is provided. The film includes: driving integrated circuit (IC) chips connected to a driving voltage supply unit external to the IC chips and the diving IC chips are adapted to receive a driving signal, a plurality of first dummy pads and a plurality of second dummy pads adapted to receive driving voltages, a first dummy voltage line connected to the first dummy pads and a second dummy voltage line connected to the second dummy pads. The driving voltage supply unit is adapted to supply the driving signal to the driving IC chips and/or the driving voltage to the first dummy pads and the second dummy pads.

According to exemplary embodiments of the present invention, the driving voltages are applied to the first and the second dummy pads which are connected to each of the first and the second dummy voltage lines binding the diode for protecting against the static electricity to the display signal lines of the liquid crystal display, such that even in the driving of the liquid crystal display, the static electricity is discharged, thereby preventing a defect due to the static electricity.

### BRIEF DESCRIPTION OF THE DRAWINGS

FIG. 1 is a schematic diagram illustrating a liquid crystal display according to an exemplary embodiment of the present invention.

FIG. 2 is an enlarged diagram of an integrated circuit chip on a film of FIG. 1.

FIG. 3 is an enlarged diagram of an A portion of FIG. 2.

### DETAILED DESCRIPTION OF EXEMPLARY EMBODIMENTS

Exemplary embodiments of present invention will be described more fully hereinafter with reference to the accompanying drawings, in which exemplary embodiments of the invention are shown. As those skilled in the art would realize, exemplary embodiments which are described herein may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present.

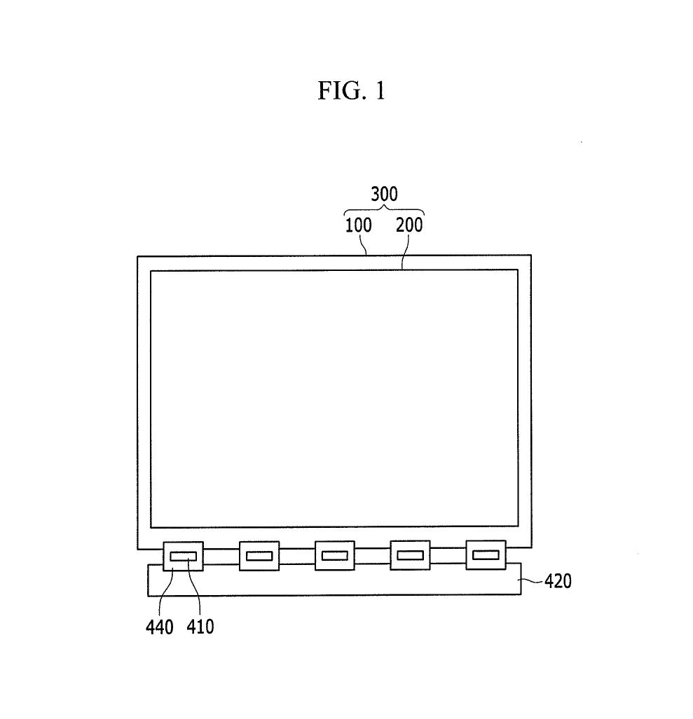

FIG. 1 is a schematic diagram illustrating a liquid crystal display according to an exemplary embodiment of the present invention.

As shown in FIG. 1, a liquid crystal display according to an exemplary embodiment of the present invention includes, for example, a liquid crystal panel 300 displaying images and a plurality of films 440 connected to the liquid crystal panel 300 and supplying a driving signal to the liquid crystal panel 300. In addition, a printed circuit board 420 receiving an image signal from the outside of the liquid crystal panel 300 to apply the driving signal to the liquid crystal panel 300 is connected to each of the film 440.

The liquid crystal panel 300 includes, for example, a thin film transistor array panel 100 including a plurality of thin film transistors (not shown), a color filter panel 200 disposed above the thin film transistor array panel 100, and a liquid crystal (not shown) injected between the panels 100 and 200.

A display area of the thin film transistor array panel 100 includes, for example, a thin film transistor on a matrix. The thin film transistor includes, for example, a source terminal, a gate terminal, and a drain terminal, and the source terminal is connected to a data line (not shown) and the gate terminal is connected to a gate line (not shown). In addition, a pixel electrode (not shown) made of, for example, transparent indium tin oxide (ITO) as a conductive material is formed in the drain terminal. The pixel electrode may also be formed of other materials including but not limited to indium zinc oxide (IZO), amorphous ITO, polycrystalline ITO and combinations thereof.

When the data line and the gate line of the liquid crystal panel 300 input an electric signal from the printed circuit board (PCB) 420, the electric signal is inputted to the source terminal and the gate terminal of the thin film transistor, and the thin film transistor is turned on or off according to the input of the electric signal such that the electric signal for forming a pixel is outputted to the drain terminal. In an embodiment of the present invention, the PCB 420 may be, for example, a flexible PCB.

Meanwhile, the color filter panel 200 is disposed above the thin film transistor array panel 100 so as to face each other. It is noted that exemplary embodiments of the present invention are not limited to the above positioning of the color filter panel 200, PCB 420 and film 440 having the IC chips formed thereon but rather, for example, the color filter panel 200 may also be disposed below the thin film transistor array panel 100 and facing each other and the PCB 420 and the film 440 having the IC chips formed thereon may be rearranged accordingly. The color filter panel 200 is a substrate in which RGB (red, green, and blue) pixels as color pixels may produce a predetermined color when light is transmitted in the liquid crystal panel 300. The color filter panel 200 is formed by, for example, a thin film process and a common electrode (not shown) made of, for example, ITO is coated on the front surface of the color filter panel 200. The common electrode may also be formed of other materials including but not limited to IZO, amorphous ITO, poly ITO and combinations thereof. When power supply is applied to the gate terminal and the source terminal of the thin film transistor to turn on the thin film transistor, an electric field is formed between the pixel electrode and the common electrode of the color filter substrate. An arrangement angle of the liquid crystals which are injected in the display area between the thin film transistor array panel 100 and the color filter panel 200 is changed due to the electric field and light transmittance is changed according to the changed arrangement angle so as to acquire a desired image.

The printed circuit board (PCB) 420 generates the driving signals for driving the liquid crystal panel 300 and a plurality of driving signals for applying the signals at an appropriate time such that the driving signals are applied to the gate line and the data line of the liquid crystal panel 300 through the film 440 on which driving IC chips 410 are mounted.

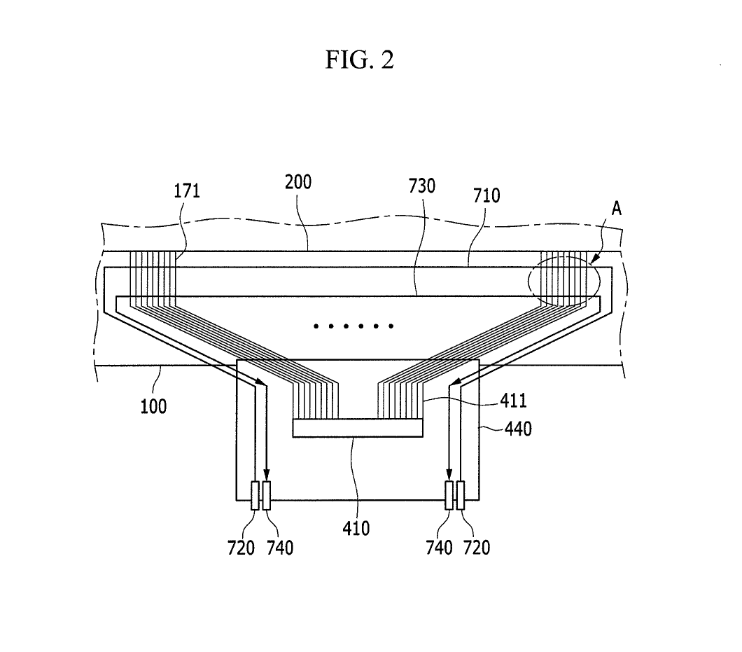

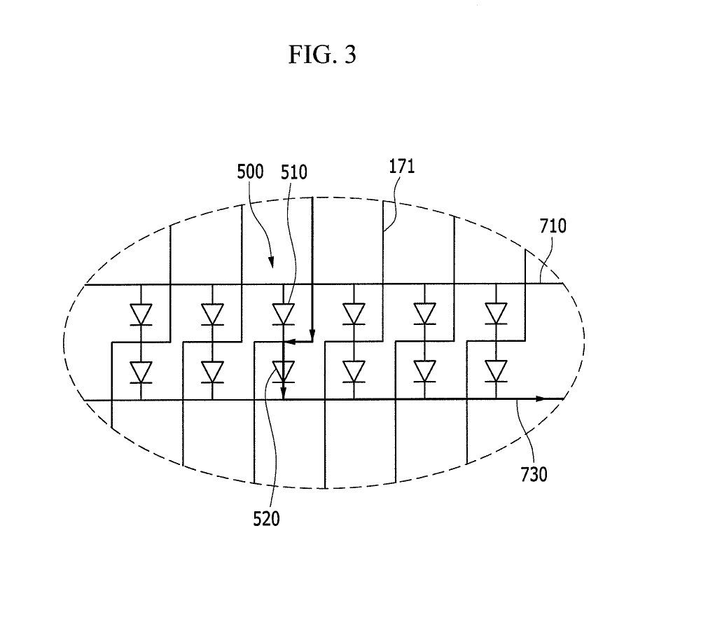

FIG. 2 is an enlarged diagram of an integrated circuit chip on a film of FIG. 1 and FIG. 3 is an enlarged diagram of an A portion of FIG. 2.

As shown in FIGS. 2 and 3, the film 440 is connected to the thin film transistor array panel 100 and a plurality of display signal lines 171 formed on the thin film transistor array panel 100 are connected with each driving signal line 411 formed on the film 440. Herein, the display signal line 171 may be, for example, a data line.

The driving IC chips 410 are mounted on the film 440 and each driving signal line 411 is connected to the driving IC chips 410. It is noted that the IC chips and driving chips 410 may also be joined to the thin film transistor array panel 100 using other techniques including, for example, Tape Carrier Package (TCP), and Chip-On Glass (CoG) techniques. Two first dummy pads 720 and two second dummy pads 740 are positioned on the film 440. A minimum voltage of the driving voltages is applied to the first dummy pads 720, and a maximum voltage of the driving voltages is applied to the second dummy pads 740. It is noted that exemplary embodiments are not limited to the above number of first dummy pads 720 and second dummy pads 740 but rather the number of first dummy pads 720 and second dummy pads 740 may be varied.

The two first dummy pads 720 are connected to each other by a first dummy voltage line 710 and the two second dummy pads 740 are connected to each other by a second dummy voltage line 730. A part of the first dummy voltage line 710 and the second dummy voltage line 730 are disposed on the thin film transistor array panel 100 and the rest of the first dummy voltage line 710 and the second dummy voltage line are disposed on the film 440.

In the present exemplary embodiment, the PCB 420 is used as a driving voltage supply unit to supply the driving voltages to the first dummy pads 720 and the second dummy pads 740. However, it is noted that exemplary embodiments of the present invention are not limited thereto but rather other units or devices such as, for example, a power unit, which are either integrated with or not integrated with the liquid crystal display 300 and which are capable of supplying driving voltages to the first and second dummy pads, 720, 740 may also be used in accordance with exemplary embodiments of the present invention.

A diode 500 for protecting against static electricity is connected to the display signal line 171. The diode 500 for protecting against static electricity includes a diode 520 connected to the display signal line 171 in a forward direction and a diode 510 connected to the display signal line 171 in a reverse direction. The diode 520 connected to the display signal line 171 in a forward direction is connected with the second dummy voltage line 730 and the diode 510 connected to the display signal line 171 in a reverse direction is connected with the first dummy voltage line 710.

When the static electricity is generated in the display signal line 171 connected to the diode 500 for protecting against static electricity, the static electricity is discharged to the first dummy pads 720 or the second dummy pads 740 through the diode 500 for protecting against static electricity. In addition, although a resistance reduction of the forward direction is generated due to the characteristic deterioration of the diode 500 for protecting against static electricity, the diode 520 connected in the forward direction and the diode 510 connected in the reverse direction are kept connected to each other in series between the adjacent display signal lines 171, such that the short of the adjacent display signal line 171 is not generated.

Further, in the driving of the liquid crystal display, the driving voltages are applied to the first dummy pads 720 connected to both ends of the first dummy voltage line 710 and the second dummy pads 740 connected to both ends of the second dummy voltage line 730, respectively, such that even in the driving of the liquid crystal display, the static electricity generated in the display signal line 171 is discharged to the first dummy pads 720 or the second dummy pads 740 through the diode 500 for protecting against static electricity.

Having described exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A liquid crystal display, comprising:
a liquid crystal panel;
a plurality of display signal lines disposed in the liquid crystal panel;
a plurality of diodes comprising a first diode and a second diode, the first diode is connected to each of the display signal lines in a reverse direction and the second diode is connected to each of the display signal lines in a forward direction;
a first dummy voltage line connected to the first diode connected to the display signal lines in the reverse direction;
a second dummy voltage line connected to the second diode connected to the display signal lines in the forward direction;
a plurality of films connected to the liquid crystal panel, wherein an integrated circuit chip supplying driving signals to the liquid crystal panel is mounted on the film; and
a plurality of first dummy pads and a plurality of second dummy pads disposed on the film,
wherein the first dummy voltage line is connected to the first dummy pads,
the second dummy voltage line is connected to the second dummy pads, and
the first dummy pads and the second dummy pads are each adapted to receive a driving voltage.

2. The liquid crystal display of claim 1, further comprising a driving voltage supply unit adapted to supply a first driving voltage to the first dummy pads.

3. The liquid crystal display of claim 2, wherein the driving voltage supply unit is adapted to supply a second driving voltage to the second dummy pads which is greater than the first driving voltage.

4. The liquid crystal display of claim 1, wherein the first dummy pads are connected to each end of the first dummy voltage line.

5. The liquid crystal display of claim 4, wherein the second dummy pads are connected to each end of the second dummy voltage line.

6. The liquid crystal display of claim 1, wherein the driving voltage supply unit is a printed circuit board (PCB).

7. The liquid crystal display of claim 1, wherein the first diode and the second diode are connected to each other in series.

8. The liquid crystal display of claim 1, wherein the first diode and the second diode are disposed between an adjacent pair of the display signal lines.

9. The liquid crystal display of claim 1, further comprising a plurality of driving signal lines disposed on the film, wherein the driving signal lines are connected to the IC chip and to the display signal lines.

10. The liquid crystal display of claim 1, wherein a portion of the first dummy voltage lines are disposed on the liquid crystal panel and a remaining portion of the first dummy voltage lines are disposed on the film and wherein a portion of the second dummy voltage lines are disposed on the liquid crystal panel and a remaining portion of the second dummy voltage lines are disposed on the film.

11. A film, comprising:
a plurality of driving integrated circuit (IC) chips connected to a driving voltage supply unit external to the driving IC chips, wherein the driving IC chips are adapted to receive a driving signal;
a plurality of first dummy pads and a plurality of second dummy pads, wherein the plurality of first and second dummy pads are adapted to receive a driving voltage;
a first dummy voltage line connected to the first dummy pads; and
a second dummy voltage line connected to the second dummy pads, and
wherein the driving voltage supply unit is adapted to supply the driving signal to the driving IC chips and/or the driving voltage to the first dummy pads and the second dummy pads.

12. The film of claim 11, wherein the driving voltage supply unit is adapted to supply a first driving voltage to the first dummy pads.

13. The film of claim 12, wherein the driving voltage supply unit is adapted to supply a second driving voltage to the second dummy pads which is greater than the first driving voltage.

14. The film of claim 11, wherein the first dummy pads are connected to each end of the first dummy voltage line.

15. The film of claim 14, wherein the second dummy pads are connected to each end of the second dummy voltage line.

16. The film of claim 13, wherein the driving voltage supply unit is a printed circuit board (PCB).

17. The film of claim 11, wherein the driving voltage supply unit is a printed circuit board (PCB) which is adapted to supply the driving voltage to the first dummy pads and the second dummy pads and to supply the driving signal to the driving IC chips.
